(19) United States
(12) Patent Application Publication
(10) Pub. No.: US 2010/0275977 A1
(43) Pub. Date: Nov. 4, 2010

(54) PHOTOVOLTAIC ARRAY AND METHODS

(75) Inventors: Richard Dale Kinard, Wilmington, DE (US); Michael Robert Mc Quade, Greenville, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. Du Pont De Nemours And Company, Wilmington, DE (US)

(21) Appl. No.: 12/809,702

(22) PCT Filed: Dec. 22, 2008
(86) PCT No.: PCT/US08/87888

§ 371 Date: Jun. 21, 2010

Related U.S. Application Data
(60) Provisional application No. 61/015,829, filed on Dec. 21, 2007.
(60) Provisional application No. 61/104,831, filed on Oct. 13, 2008.

(51) Int. Cl. H01L 31/048; H01R 43/00

(52) U.S. Cl. 136/251; 29/825

(57) ABSTRACT

A photovoltaic array having a plurality of photovoltaic modules having first structural members. The photovoltaic modules are disposed upon and connected to a plurality of framework elements. The framework elements being interconnected to form a framework. The framework elements have electrically non-conductive second structural members with internally disposed electrical conductors. Electrical and mechanical connections to the photovoltaic module disposed upon the framework element and electrical connections among framework elements are internal to the framework elements. The output voltage of the photovoltaic array can be electrically referenced to an arbitrary voltage.

This application claims the benefit of U.S. Provisional Applications, 61/015,829 filed Dec. 21, 2007 and 61/104,831 filed Oct. 13, 2008, which are all herein incorporated by reference.

### FIELD OF INVENTION

The present invention is directed to a photovoltaic array having an interconnected electrically non-conductive framework. The array does not have to be electrically grounded.

### BACKGROUND

Commercially available solar energy photovoltaic arrays involve a large number of electrically conducting metallic structural components that need to be grounded.

Erling et al., U.S. Pat. No. 7,012,188, discloses a system for roof-mounting plastic enclosed photovoltaic modules in residential settings.

Mapes et al., U.S. Pat. No. 6,617,507, discloses a system of elongated rails of an extruded resin construction having grooves for holding photovoltaic modules.

Metten et al., U.S. Patent Publication 2007/0157963, discloses a modular system that includes a composite tile made by molding and extrusion processes, a track system for connecting the tiles to a roof, and a wiring system for integrating photovoltaic modules into the track and tile system.

Garvison et al., U.S. Pat. No. 6,465,724, discloses a multipurpose photovoltaic module framing system which combines and integrates the framing system with the photovoltaic electrical system. Some components of the system can be made of plastic. Ground clips can be directly connected to the framing system.

The present invention fills a need for a photovoltaic array having an interconnecting electrically non-conducting framework. The framework houses electrical components and is typically made of a plastic. Therefore, electrical grounding is unnecessary without compromising safety or operability.

### SUMMARY OF THE INVENTION

The invention is directed to a photovoltaic array comprising a plurality of photovoltaic modules comprising first structural members, the photovoltaic modules disposed upon and mechanically and electrically connected to a plurality of framework elements; the framework elements being mechanically and electrically interconnected to form a framework; the framework elements comprising electrically non-conductive second structural members comprising internally disposed electrical conductors, electrical and mechanical connections to the photovoltaic module disposed upon the framework element, and electrical and mechanical connections among the framework elements; the framework comprising an electrical output to permit connection to an external electrical load and wherein the output voltage of the photovoltaic array can be electrically referenced to an arbitrarily selected voltage that is not ground.

The invention is further directed to a method comprising illuminating a photovoltaic array with sunlight to generate an electrical current from the photovoltaic array, the photovoltaic array comprising a plurality of photovoltaic modules comprising first structural members, the photovoltaic modules disposed upon and mechanically and electrically connected to a plurality of framework elements; the framework elements being mechanically and electrically interconnected to form a framework; the framework elements comprising electrically non-conductive second structural members comprising internally disposed electrical conductors, electrical and mechanical connections to the photovoltaic module disposed upon the framework element, and electrical and mechanical connections among the framework elements and applying the electrical voltage so generated to an external electrical load.

The invention is still further directed to a method comprising disposing a plurality of photovoltaic modules into a plurality of framework elements, each the photovoltaic module comprising a first structural member, the photovoltaic modules being equipped with electrical and mechanical connectors, each the framework element comprising a second structural member comprising internally disposed electrical conductors, electrical and mechanical connectors to the photovoltaic module disposed upon the framework element, and electrical and mechanical connectors for interconnecting each framework element to at least one other framework element thereby forming a framework; connecting the photovoltaic module to the framework element electrically and mechanically; and, interconnecting the framework elements with one another to form a photovoltaic array whereof the output voltage can be electrically referenced to an arbitrarily selected voltage.

### BRIEF DESCRIPTION OF THE DRAWINGS

The invention will be more fully understood from the following detailed description taken in connection with the accompanying Figures, which form a part of this application and in which:

FIG. 1A illustrates a residential rooftop upon which is disposed a photovoltaic array.

FIG. 1B illustrates the basic components that make up a photovoltaic module.

FIGS. 1C-1E illustrate embodiments of structurally supported photovoltaic modules.

FIGS. 2A-2E illustrate an embodiment of framework construction and framework attachment shoes to a residential roof.

FIG. 3A illustrates an embodiment of a wiring harness and connections found within a framework design.

FIGS. 3B-3D illustrate embodiments of internally enclosed jumper wires and connectors built into the framework design.

FIG. 4A illustrates an embodiment of a framework element with electrical connection alternatives.

FIG. 4B illustrates an embodiment of mechanical connectors on the framework element.

FIG. 4C illustrates an embodiment wherein weather-proof connectors are employed for effecting the electrical connections between the cables leading from the junction box of a photovoltaic module to the framework element.

FIG. 4D illustrates a recessed connecting element that is built into the structural member of the framework element, that is suitable for use when the photovoltaic module comprises internally disposed connecting elements that align with the connecting element shown in the figure.

FIG. 4E illustrates an embodiment of a photovoltaic module used in a method for attachment onto a framework element, and alternative embodiments for effecting the electrical connection. On the left of the FIG. 4E is a junction box with cables, and on the right of FIG. 4E is a junction box with bulkhead mounted connectors lined up with connectors on the framework element.

FIG. 4F illustrate an embodiment of a photovoltaic module used in a method for attachment onto a framework element wherein the electrical connection elements are integrated into the frame of the photovoltaic module.

FIG. 4G illustrates a breakout embodiment of a connection element built into the framework element of FIG. 4F.

FIG. 5A illustrates an embodiment of a photovoltaic array wired in series.

FIG. 5B illustrates an embodiment of a photovoltaic array wired in the combination of parallel and series.

FIGS. 5C-5E illustrate wiring harness and links.

### DETAILED DESCRIPTION

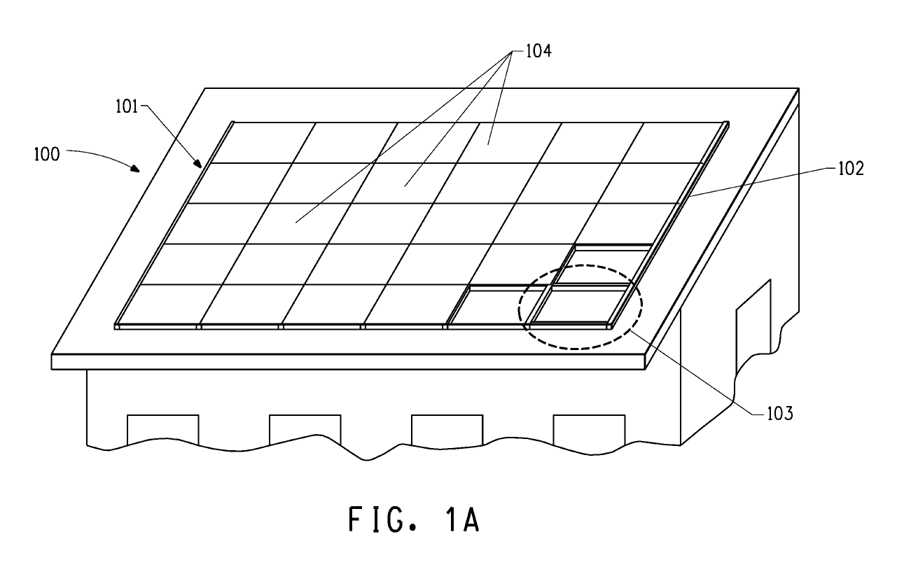

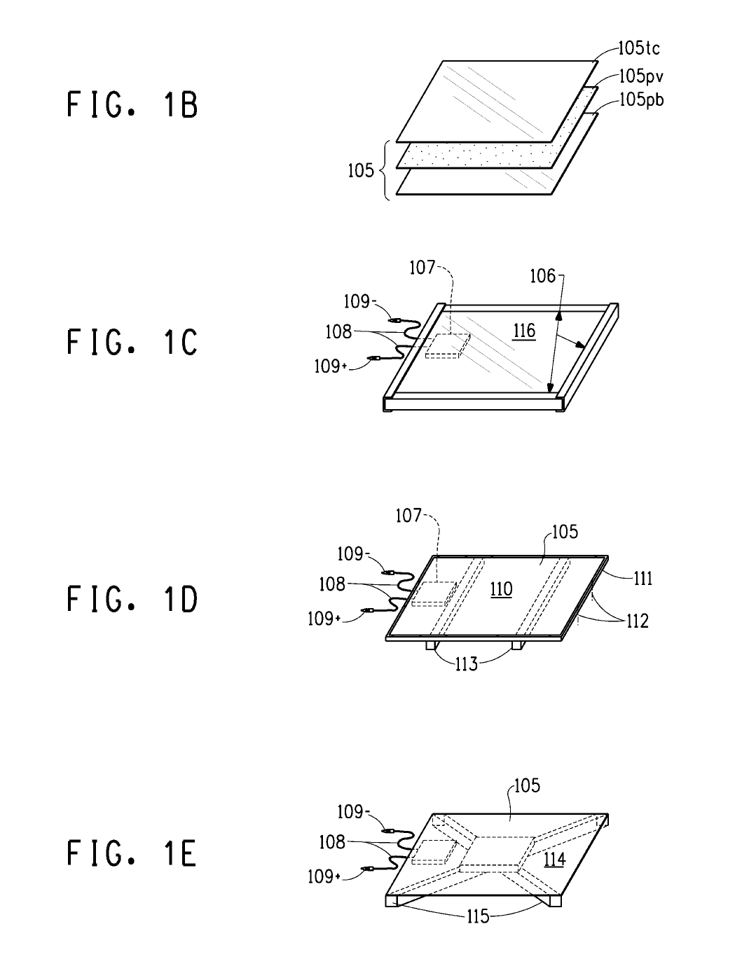

A photovoltaic (PV) array (101) illustrating an arrangement of photovoltaic modules (104) positioned to convert sunlight (or other illumination) to electrical power is shown in FIG. 1A. In one embodiment such an array comprises a single photovoltaic module. In another embodiment a photovoltaic array involves a plurality of photovoltaic modules each photovoltaic module may include about 50 to 100 individual photoelectric cells having coplanar arrangement, and the plurality of photovoltaic modules also arranged in coplanar arrangement. In an embodiment of a commercial installation, a single photovoltaic module can output 30 amps of current at 24 volts, and a photovoltaic array can output 30 amps at about 500 to 1000 volts. As used herein, the phrase “solar panel” represents a sub-class of photovoltaic modules that is specifically designed with the sun as an energy source. The terms “photo cell” and “photovoltaic cell” are synonymous.

Safely handling electrical power levels and voltage levels of such a magnitude in outdoor commercial and residential settings using the photovoltaic arrays of the art requires numerous precautions, including the grounding of all exposed metal structural parts; and the protection of all non-weather resistant connections from corrosion. In the present invention, electrical conductors and connectors are partially contained or completely contained within the shell of the non-electrically conducting structural members or isolated in their own non-conductive housing. In an embodiment, no exposure of connectors to corrosive conditions occurs. The photovoltaic array hereof is characterized in that all of its internal electrical components: including photovoltaic cells, by-pass diodes, internal intraconnections, internal interconnections are encased in and supported by non-conductive framework elements or other non-conductive housing. The photovoltaic array allows the output voltage to be electrically referenced to any arbitrary voltage without compromising safety or system integrity. Therefore, no electrical grounding is required.

In addition to the benefits in installation cost and safety associated with the photovoltaic array of the invention, there is also a benefit in increased electrical design flexibility over the photovoltaic arrays of the art because the system may be installed under conditions where the reference voltage is well above ground potential—something not possible with systems of the art.

As used herein, a framework is a structure made up of framework elements that are interconnected both mechanically and electrically to form the framework. In the photovoltaic array a framework element holds a photovoltaic module that is mechanically and electrically connected to the framework element.

In general terms, a photovoltaic module (105) comprises a structural component, a plurality of electrically interconnected photovoltaic cells (105pv) arranged in a parallel coplanar array with an optically clear protective cover layer (105tc), and a protective backing layer (105pb); the photovoltaic cells being sandwiched and sealed between the cover layer and the backing layer, as shown in FIG. 1B. In one embodiment the structural component of the photovoltaic module is a peripheral frame (106) (a first structural component) (FIG. 1C). In an alternative embodiment the structural component is an underlying supporting structure (113 & 115) (FIGS. 1D and 1E). In still another embodiment, the photovoltaic module further comprises an electrical junction box (107) (FIGS. 1C-1E). In a further embodiment, the photovoltaic module has high voltage connecting cables with weather-resistant plugs. In an alternative embodiment, the photovoltaic module is provided with integrated electrical connections within the structure of the module.

Any photocell that absorbs sunlight is suitable for the practice of the invention. A suitable photovoltaic cell comprises layers of doped and undoped silicon layers, sandwiched between two layers of metal conductors. A suitable photovoltaic cell converts impinging sunlight into electrons and holes, which then migrate to the metal conductors to create an electrical current. There are many types of photovoltaic cells in the art, single layer, double layer, triple layer, etc., any of which could be used with this invention, if formed together and electrically interconnected to form a power producing photovoltaic module.

Several semiconductor compositions have been developed in the art for use as photovoltaic cells in solar panels. The operability of the present invention, and the attainment of the desirable benefits does not depend upon the particular photovoltaic cell that is employed in the photovoltaic module. Many useful photovoltaic modules are commercially available. The photovoltaic modules that represent designs that employ the same photovoltaic cells that have been used since the beginning of solar energy generation.

More broadly, a photovoltaic cell is a semiconductor electrical junction device which absorbs and converts the radiant energy of sunlight directly into electrical energy. Photovoltaic cells are connected in series and/or parallel to obtain the required values of current and voltage for electric power generation as in the photovoltaic array.

The conversion of incident light such as sunlight into electrical energy in a photovoltaic cell involves absorption of incident light by a semiconductor material; generation of electrons and holes, migration of the electrons and holes to create a voltage, and application of the voltage so generated across a load to create an electric current. The heart of the photovoltaic cell is the electrical junction which separates the electrons and holes from one another after they are created by the absorption of light. An electrical junction may be formed by the contact of: a metal to a semiconductor (this junction is called a Schottky barrier); a liquid to a semiconductor to form a photo-electrochemical cell; or two semiconductor regions (called a pn junction). The pn junction is most common in photovoltaic cells.

Crystalline silicon and gallium arsenide are typical choices of materials for photovoltaic cells. Dopants are introduced into the pure compounds, and metallic conductors are deposited onto each surface of the cell: a thin grid on the sun-facing side and a flat sheet on the other side. Typically, photovoltaic cells are made from silicon boules, polycrystalline structures that have the atomic structure of a single crystal. The pure silicon is then doped with phosphorous and boron to produce an excess of electrons in one region and a deficiency of electrons in another region to make a semiconductor capable of conducting electricity.

Photovoltaic modules suitable for the practice of the present invention are available commercially from a number of manufacturers, such as Evergreen Solar, Inc, Marlboro, Mass.; Solarworld California, Camarillo, Calif., and Mitsubishi Electric Co., New York, N.Y.

The photovoltaic modules mounted on and electrically connected to the assembled framework form the photovoltaic array capable of producing electrical power from sunlight.

Any electrically non-conductive, engineered, structural material including ceramics, wood, and plastic could be used to form the structural members of the photovoltaic modules and the framework elements. If the material is classified as a non-conductor according to appropriate regional Standards Organizations, such as UL (Underwriters Laboratories), cUL, or TUV, it is appropriate for use in this invention. To be UL certified, materials must meet UL 1703 (Standard for Safety for Flat-Plate Photovoltaic Modules and Panels); UL 498 (Attachment Plugs and Receptacles); and/or UL 1977 (Component Connectors Used for Data, Signal and Power Equipment Applications), as appropriate. Additional information on UL certification can be found at http://www.ul.com/dge/photovoltaics/ and http://www.ul.com/dge/photovoltaics/tests.html

The term plastic encompasses organic polymers that can be thermoplastic or thermoset. Suitable organic polymers are rigid solids up to about 90° C. The term “plastic” includes unreinforced polymers, filled polymers, short fiber reinforced polymers, long-fiber reinforced polymers, continuous-fiber reinforced polymers (also known as “composites”), any suitable electrically non-conductive reinforcing fiber can be used in a polymer or combinations of the above. Composites are engineered materials made from two or more constituent materials with significantly different physical or chemical properties and remain separate and distinct within the finished structure.

The plastic compositions may further comprise such additives as are commonly employed in the art of Engineering Polymers, such as inorganic fillers, ultra-violet absorbers, plasticizers, anti oxidants, flame retardants, pigmentation and so forth.

A photovoltaic module typically has an area exposed to incident sunlight of 0.5 ft² to about 15 ft² (0.05 to 1.4 m²). A large commercial module holds about 50-100 of crystalline silicon photoelectric cells usually found in a coplanar arrangement so that incident sunlight will fall upon the photocells. A plurality of photovoltaic modules is disposed within the framework elements typically in coplanar array.

In one embodiment, as illustrated in FIG. 1A, the present invention provides a photovoltaic array (101) comprising a plurality of photovoltaic modules (104) disposed within and mechanically and electrically connected to a plurality of framework elements (103) mounted on a residential rooftop (100). The framework elements are mechanically and electrically interconnected to form a framework (102). The framework elements comprise structural members (second structural members). At least some of the structural members have a guideway that fully encloses electrical conductors. Periodically the conductors will terminate through an opening in the structural member of the framework element. This is where the conductor will mate with an electrical connection from a photovoltaic module. Each framework element interconnects electrically and mechanically to at least one other framework element. The electrical connections are enclosed within at least some the structural members. The structural members are made from electrically non-conductive materials. The framework also has an electrical output for connection to an external electrical load.

In typical practice, a framework comprising a plurality of framework elements is first constructed, followed by introduction of a plurality of photovoltaic modules to form a photovoltaic array. After the panels are secured to the framework elements, and the electrical connections between photovoltaic modules and framework elements have been made, then is a connection made to an external load.

The electrically non-conductive structural members constitute the exterior surface of the framework. In one embodiment, the photovoltaic module and the framework is provided with plastic structural members. In another embodiment, the photovoltaic module has metallic structural members, necessitating that the metallic members be subject to encapsulation in plastic. Any means for encapsulating in plastic is satisfactory, for example, coatings, extrusions, laminations, bonding, cladding, with the proviso that the encapsulation be weather-resistant or weather-proof.

The electrical conductors can be in any convenient form for example electrical wires, conductive strips such as buss bars, printed circuits and the like. In one embodiment mechanical connections between framework elements are made of plastic, and the elements snap together. Mechanical connections may be reversible to make replacement of damaged parts easy. Suitable mechanical connections include, but are not limited to: snap-together, spring-loaded, quarter-turn, bayonette, interlocking, and quick connect/disconnect assemblies such as those used in the discrete-part manufacturing industry.

Electrical connections between framework elements may conveniently be effected using conventional high voltage connectors wherein the male connector is located on one component, disposed to mate with the female component disposed on the component to which it is to be connected. Suitable connectors are preferably approved for photovoltaic applications by organizations such as UL and TUV.

Each photovoltaic module is disposed in and connected electrically and mechanically to a framework element. The photovoltaic module is provided with both mechanical and electrical connectors compatible with complementary connectors provided in the framework element to which it is connected. Suitable mechanical connections provided in the photovoltaic module include a frame that snaps into a receiving track on the framework element, pass-through holes in a frame on the photovoltaic module for mounting to the framework element. In the case where pass-through holes are employed, the mounting screws and mating fasteners, such as threaded standoffs, rivets, inserts or nuts, are either insulated or isolated from the framework elements made of plastic, coated with an insulating surface, capped with an insulating cover or combinations. Electrical connectors should be certified for outdoor use in wet locations with exposure to sunlight (i.e., UV exposure resistance). Power connectors for use with photovoltaic modules and framework should be designed robustly enough to withstand use as a DC circuit interrupt device, under overload conditions, as outlined in UL 498 and UL 1977.

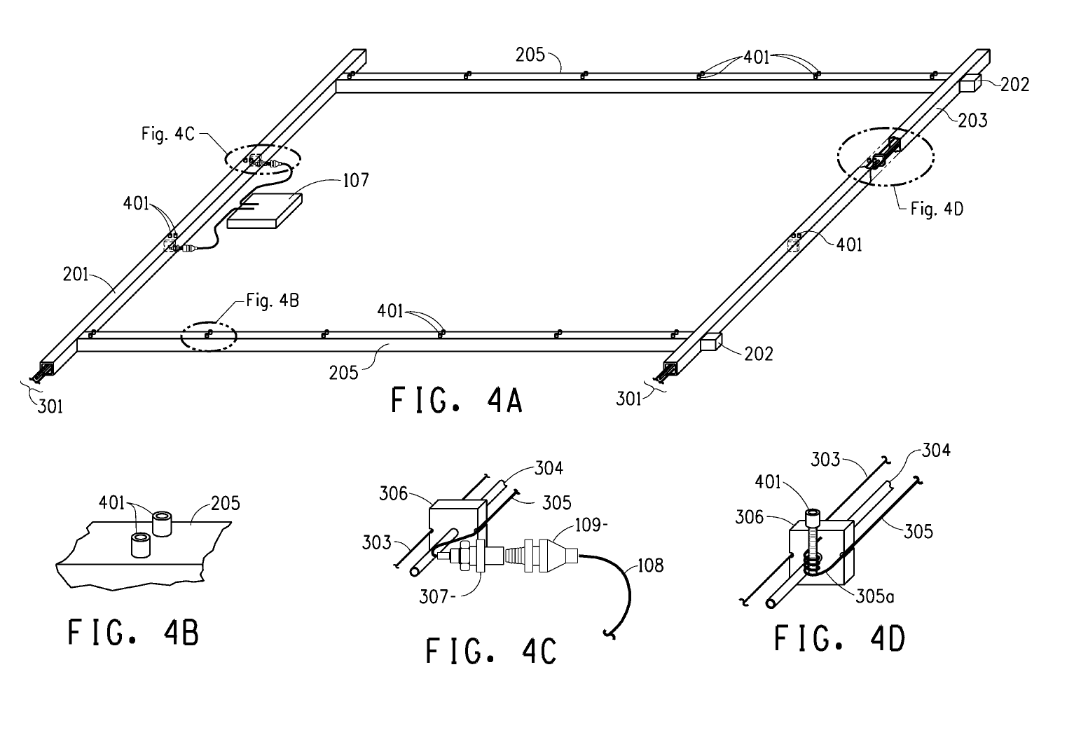

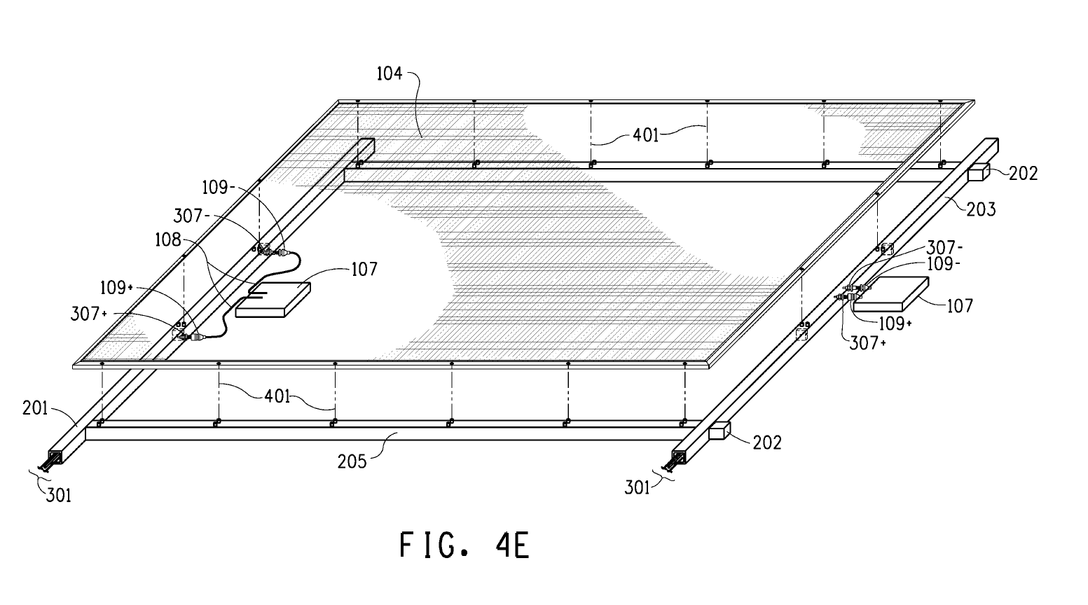

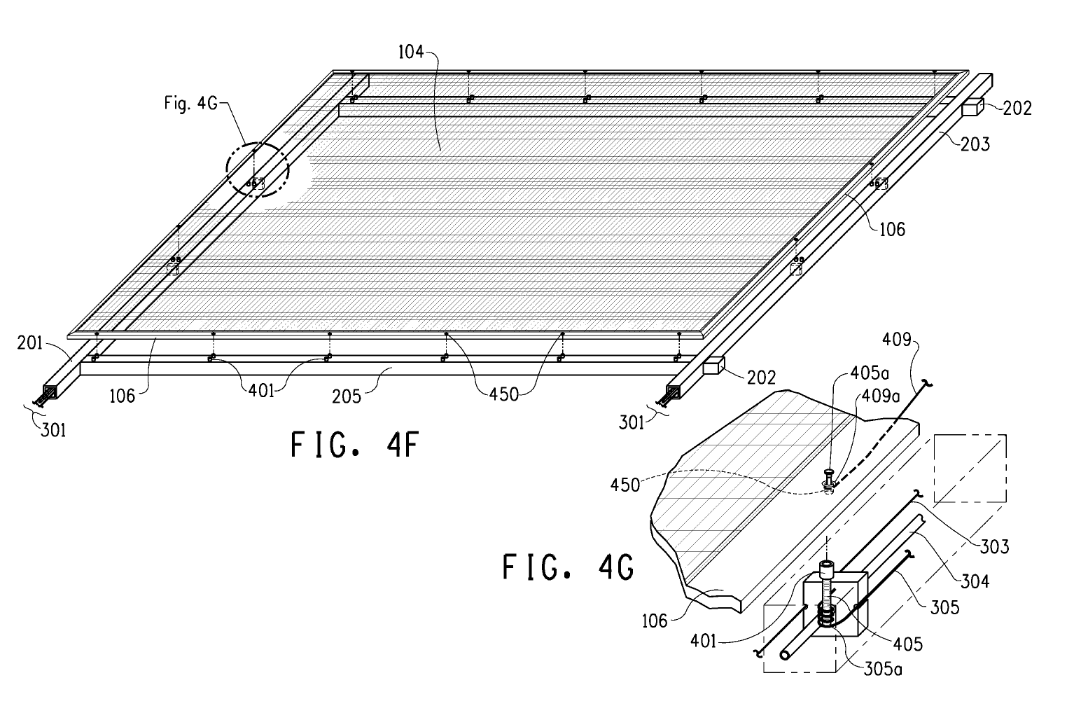

In one embodiment, the photovoltaic module (104) is provided with output conductors that are connected to a junction box (107) mounted on the back of the photovoltaic module that in turn provides high voltage output wires having weather-tight connectors at the end, as illustrated in FIG. 4E, on the left side. The output high voltage wires are connected into the framework wiring.

In another embodiment the output high voltage wires are replaced by high voltage connectors bulkhead mounted on the junction box, and inserted directly into complementary connectors mounted on the framework element, as illustrated in FIG. 4E on the right side.

In another embodiment, the photovoltaic module has no external wires. Instead the output wires are run within the panel frame to connectors that are coincident with through-holes in the frame that match up to mounting posts on the framework element, thereby achieving both mechanical securing and electrical connection at the same time, as shown in FIGS. 4F and 4G.

The framework has a plurality of framework elements with structural members that require no grounding and completely enclose all electrical conduction and connections. In one embodiment, the structural members are made of plastic. The selection of specific types of plastic suitable for use herein depends greatly upon the type of application and the location. For example, a rooftop installation where plastic members are secured to roof rafters may permit the use of unreinforced engineering plastics, either thermoplastic or thermoset. On the other hand, commercial installations, involving flat roofs, or ground based arrays, are typically elevated at an angle of about 15-40° depending upon the latitude and the time of year.

In such applications, the framework needs to be self-supporting over a wide range of conditions. In that case, unreinforced plastics may be unsuitable due to inadequate mechanical strength in hot desert environments, excessive long-term creep, or loss of physical properties due to UV degradation, but reinforced plastics will be suitable, including short-fiber reinforced polymers, long-fiber reinforced polymers, and continuous fiber reinforced polymers.

The term “short fiber reinforced polymer” is a term found in the art referring to a blend of a polymer and a reinforcing fiber characterized by a length of less than about 5 mm, wherein the fiber is dispersed with a continuous matrix of the polymer. The term “long fiber reinforced polymer’ is a term of art referring to a blend of a polymer and a reinforcing fiber characterized by a length of about >5 mm-50 mm, wherein the fiber is dispersed with a continuous matrix of the polymer. Continuous fiber reinforced polymers are also known as composite materials. Continuous fiber reinforced polymers generally involve fibers that are comparable in length to the article into which they have been incorporated.

Short and long fiber reinforced polymers may be prepared by extrusion blending, and fabricated by injection molding. Continuous fiber reinforced polymers must be prepared by yarn coating, polymer infusion into yarn bundles and the like. Fabrication may involve vacuum molding, pultrusion and such other methods that have been developed in the art for shaping of composite materials.

Suitable reinforcing fibers include glass fibers, polyaramid fibers, ceramic fibers, and other non-electrically conductive fibers that retain their distinctive fiber properties during processing and fabrication. Fiber reinforced polymers are extremely well-known in the art. Detailed descriptions of compositions, preparation, fabrication, and properties may be found in Garbassi et al. J. Poly. Sci. and Tech., DOI 10.1002/0471440264.pst406, and Goldsworthy et al., J. Poly. Sci. and Tech., DOI 10.1002/0471440264.pst074.

In terms of the choice of polymers, in a bone dry climate such as a desert, nylon polyamide may offer a desirable combination of properties. In a temperate climate, periods of rain and high humidity will render the nylon subject to dimensional instabiliity and hydrolysis. For many purposes, pultruded square cross-section hollow fiber reinforced polyethylene terephthalate resin is highly satisfactory and cost effective.

Suitable plastics need to exhibit dimensional stability when subject to continuous operating temperatures as high as 90-120° C. Many plastics such as polyolefins soften at temperatures below that temperature. Softening is unacceptable both from the standpoint of maintaining coplanarity of the photovoltaic modules and the photovoltaic cells of which they are composed, and of flexural, shear, and torsional resistance. Plastics suitable for the practice of the invention include but are not limited to polyamides, such as nylons, polyesters such as polyethylene terephthalate, polycarbonate, poly ether ketones, including PEK, PEEK, PEKK and the like; polyamideimides, epoxies, and polyimides. Rynite® PET polyester resin available from DuPont is satisfactory for most embodiments.

In another aspect, the present invention provides a method comprising illuminating a photovoltaic array with sunlight wherein the array comprises a plurality of photovoltaic modules disposed within and mechanically and electrically connected to a plurality of framework elements. The framework elements are mechanically and electrically interconnected to form a framework. The framework elements comprise second structural members. The structural members have a passage to accommodate electrical conductors. Periodically the conductors will terminate through an opening in the structural member of the framework element. This is where the conductor will mate with an electrical connection from a photovoltaic module. Each framework element interconnects electrically and mechanically to at least one other framework element. The electrical connections are enclosed within at least some the structural members. The structural members are made from electrically non-conductive materials. The framework also has an electrical output for connection to an external electrical load, and connecting the output to an external load.

While the method can be practiced by connecting the output of the photovoltaic array to an electrical load, it is anticipated that in general the output will be processed in a number of ways to make it more useful. In a typical application the direct current (DC) output of the photoarray will be directed to a DC to AC power inverter and thence to a transformer either for conditioning for long distance high voltage power transmission, or for low voltage local power use.

The output of the photovoltaic array can be delivered by hardwiring an output cable to an external electric component such as a power inverter, to convert the high voltage DC generated by the photovoltaic cells to the applicable utility grid voltage, frequency and cycles (120 vAC-60 hz-1 phase or 480 vAC-60 hz-3 phase in the US). Alternatively, the array can be provided with a high voltage output disconnect that connects to the external cable. Alternately, the output of the photovoltaic array could be used to charge electrical storage devices.

When the photovoltaic array is employed according to the method, the array is most effective when positioned to receive the maximum amount of sunlight. At temperate latitudes, the array is maintained at an angle in the range of 15 to 40° with respect to the horizontal. It is preferable to adjust the angle from time to time as the angle of the sun in the sky changes with the seasons.

In another embodiment of the invention, a method is provided comprising disposing a plurality of photovoltaic modules having electrical and mechanical connections into a plurality of framework elements. Each framework element comprises second structural members at least some of which structural members enclose electrical conductors. Electrical and mechanical connectors for connecting to a photovoltaic module are disposed within the structural members of the framework. Electrical and mechanical connectors are disposed therewithin for interconnecting each framework element to at least one other framework element. In some embodiments the electrical connectors are enclosed within the structural members. In some embodiment the electrical connectors are fully enclosed. In some embodiments the structural members are shaped plastic articles. The photovoltaic modules are connected to the framework element electrically and mechanically, and the framework elements are interconnected with one another.

The electrical and mechanical connectors, structural members, and the definitions described supra are applicable equally to the method.

In one embodiment of the invention, all electrical connections and wiring for the entire array are enclosed in the structural member. In an alternative embodiment, all electrical connections and wiring for the entire array are enclosed in the structural member with the exception of weather-tight high voltage connections between the photovoltaic module and the framework element with which it is associated. In both embodiments, grounding connections are unnecessary because there is nothing to ground.

In the embodiment wherein all electrical connections and wiring for the entire array are enclosed in the structural member, electrical connections are made as the array is mechanically assembled. In the case where junction boxes and weather-tight high voltage cables are employed, some wiring in-the-field continues to be necessary.

In one embodiment, the output cables from the junction box are eliminated and weather-tight high voltage connectors are mounted directly on the junction box and the box is located so that the connectors snap into connection with the framework element as the photovoltaic module is being installed into the framework element.

In an alternative embodiment, the junction box is eliminated altogether and the wiring of the photovoltaic module resides entirely inside the photovoltaic module structure. In this embodiment, the electrical and mechanical connection can be combined into a single part allowing the simultaneous connection of the panel electrically and mechanically.

These and other embodiments are depicted in FIGS. 1-5. Throughout the following detailed description similar reference numerals refer to similar elements in all figures of the drawings. It should be understood that various details of the structure and operation of the present invention as shown in various Figures have been stylized in form, with some portions enlarged or exaggerated, all for convenience of illustration and ease of understanding.

FIGS. 1-5 show schematically several closely related embodiments of the device and the method for assembling a photovoltaic array. In the embodiments, the photovoltaic array is installed on a residential, slanted rooftop, common in many parts of the United States. The figures represent only a few of many framework/photovoltaic module geometries possible by this invention.

Numerous other embodiments are envisioned to fall within the invention. These include but are not limited to installations on flat roofs and on the ground. Additional embodiments include but are not limited to those wherein each framework element is individually constructed, and then snapped together in the field to form the array.

One embodiment that can be constructed from those depicted in the figures is an embodiment in which all electrical conductors and connections are fully contained within the framework.

FIG. 1A illustrates one embodiment of a photovoltaic array 101 installed on residential rooftop 100. The photovoltaic array, 101, comprises a framework, 102, each framework element, 103, mechanically and, in some embodiments, electrically connected to another framework element with internal electrical Interconnects. Each framework element, 103, holds a photovoltaic module 104.

FIG. 1B shows the basic sandwich structure, 105, that depicts a general photovoltaic module wherein a photocell array 105pv is located between a clear, protective top layer 105tc, and the protective bottom layer 105pb. Also, shown FIG. 1C through 1E are various types of photovoltaic modules, 116, 110, and 114. Each type of photovoltaic module comprises one or more structural members such as a frame 106 shown in FIG. 1C, in other embodiments support beams in FIG. 1D shown as 113, and in FIG. 1E shown as 115. In one embodiment the structural members of the photovoltaic module are plastic such as a fiber reinforced plastic. Structural members of the photovoltaic module include but are not limited to framing, backing, beams, or other such elements as are required to hold the multi-layer photovoltaic module together, and to resist flexure. In one embodiment the photovoltaic module 116 has a peripheral supporting structural frame 106 that achieves adequate rigidity through a thick, rigid, extrusion surrounding the photovoltaic module. Alternatively, the same degree of structural support can be achieved with a light-weight supporting frame and structural stiffeners 113 bonded to the backside of the photovoltaic module, 110. Alternatively, module 114 has an integrated backside supporting structure 115 In all cases, the brittle, easily damaged photovoltaic cells should be adequately supported and protected to prevent micro-cracking during violent weather if the output of the photovoltaic module is to remain intact for its desired lifetime.

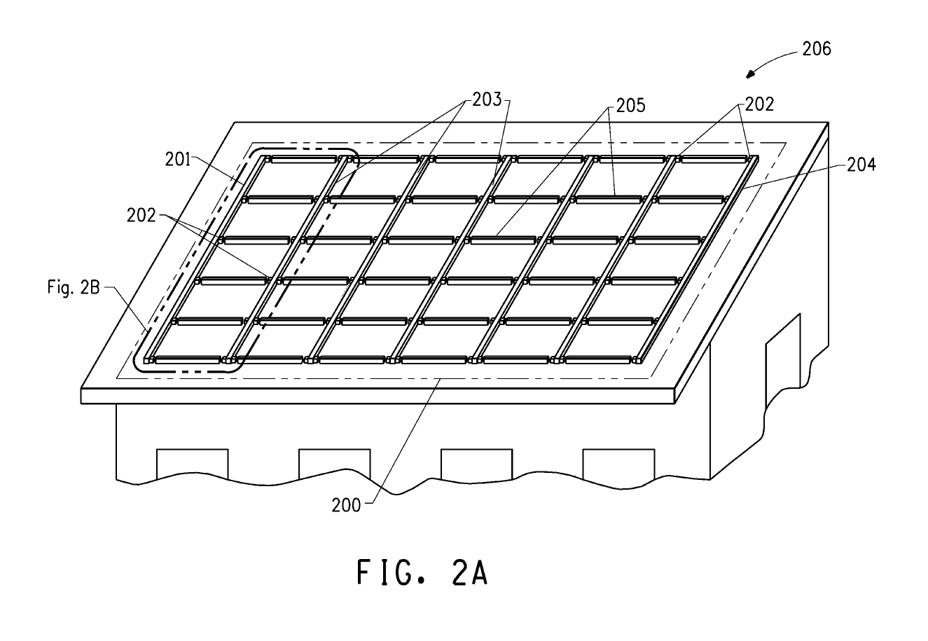

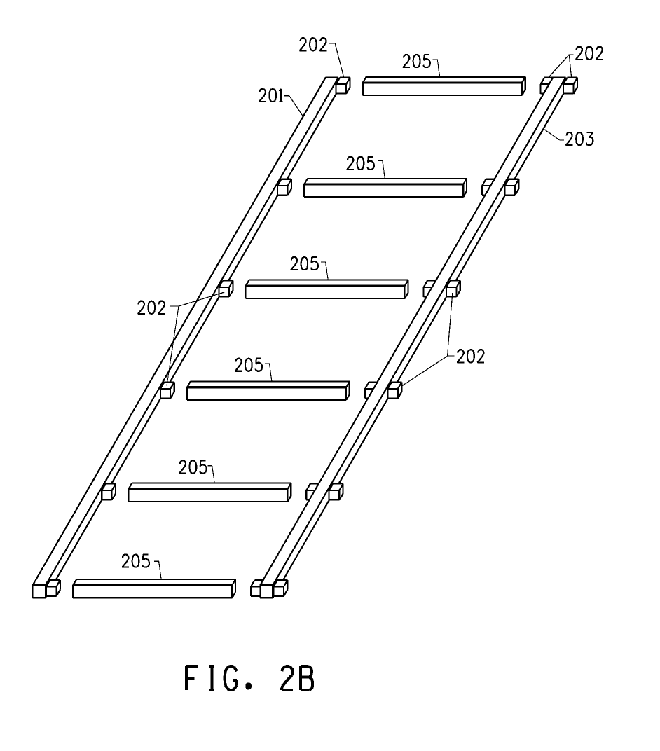

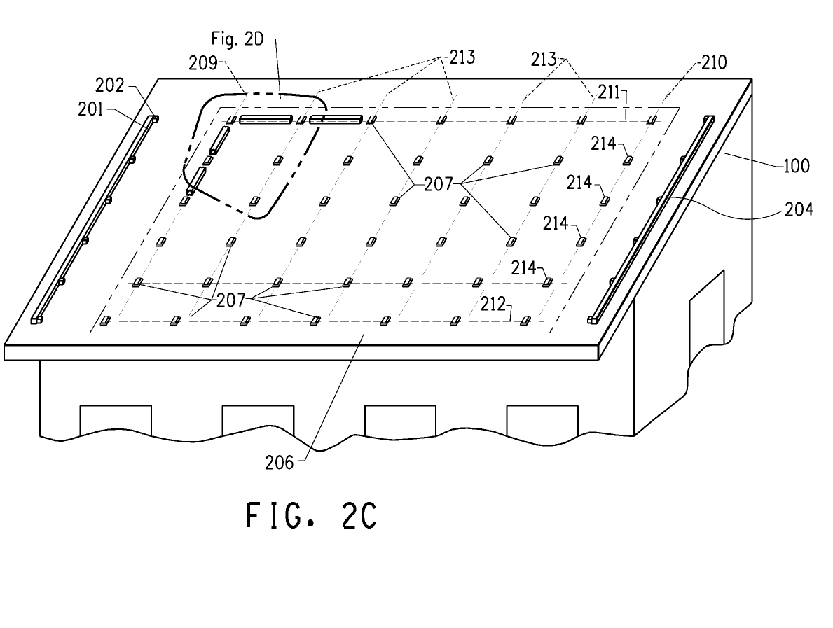

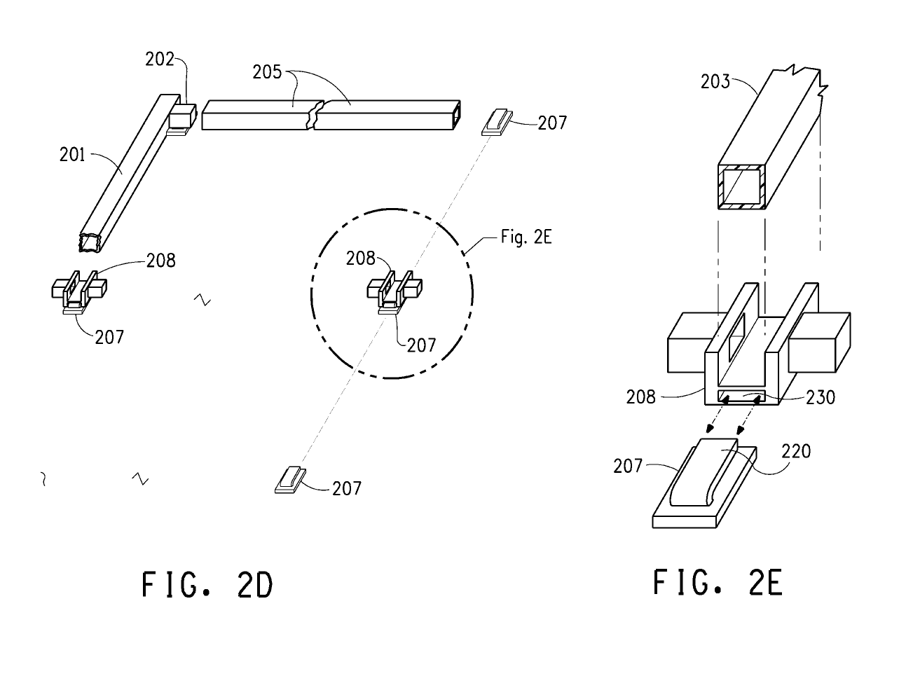

FIGS. 2A and 2B (FIG. 2B is a break-out illustration of FIG. 2A as designated in FIG. 2A) illustrate an embodiment of the method for directly assembling an array of framework elements 103 into the photovoltaic array 101. A first end member, 201, made from 5 cm×5 cm (2×2) cross-section, hollow, fiber-reinforced plastic (FRP) tubing, forms one side of a framework, and a second end member, 204, forms the opposite side of the framework 200. The first end member 201 interconnects with a plurality of rectangular cross section hollow FRP tubing cross-members, 205. Each cross-member 205 is further connected at the opposite end with an intermediate member, 203, of rectangular cross-section hollow FRP tubing provided with plastic interconnects, 202. Unlike the end-members above the intermediate members, 203, are provided with plastic interconnects facing in opposite directions so that the intermediate members 203 can interconnect to cross pieces 205 on both sides of the intermediate member.

FIGS. 2C through 2E illustrate embodiments comprising a matrix of mounting shoes, 207, which attach to the roof, 100, at premeasured locations 209-214, in order to secure the framework members 201, 203, 204 and 205, via mounting feet, 208, affixed beneath some or all of the plastic interconnects, 202. In an embodiment the feet can be plastic. In an embodiment shown in FIG. 2E, the mounting feet, 208, are U shaped pieces, with an open channel 230 in the bottom, which engages the roof-mounted, mating tongue 220 on each corresponding mounting shoe, 207.

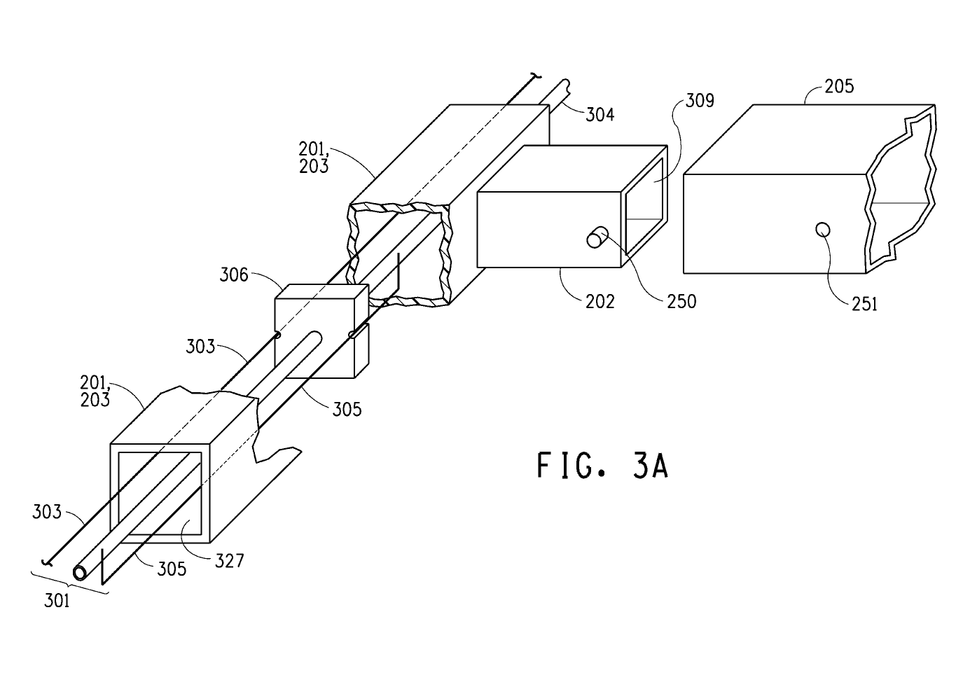

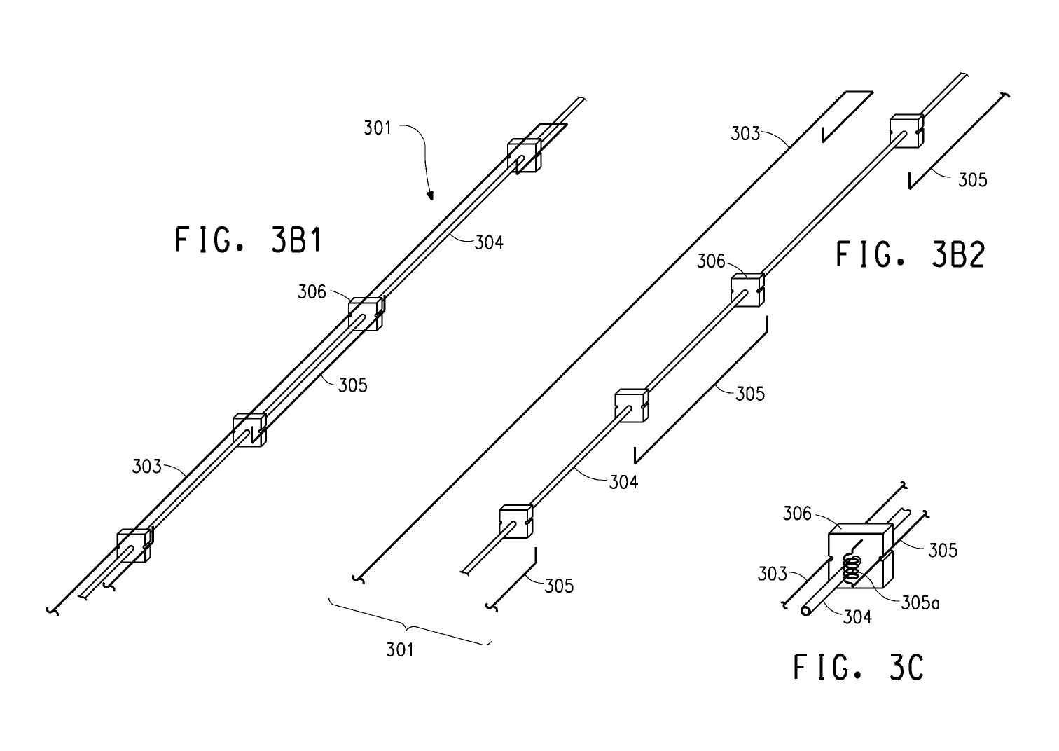

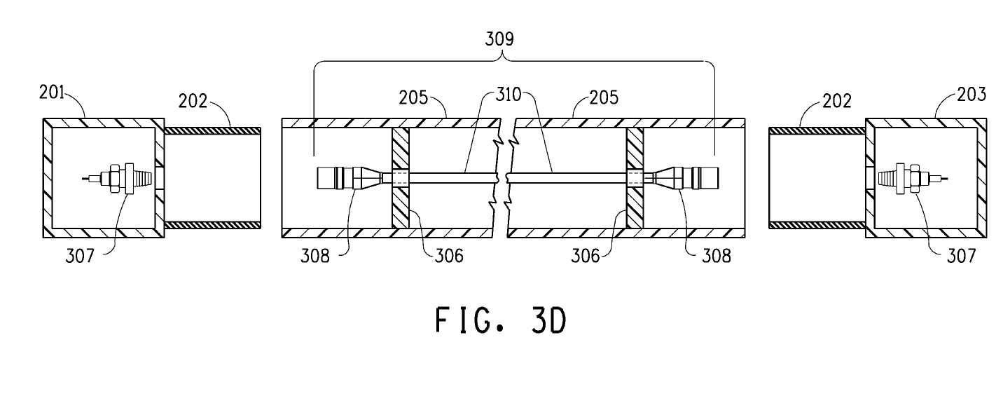

Referring to FIG. 3A, each member 201, 203 or 204 (not shown), can contain an internal electrical interconnect wiring harness, 301. In an embodiment shows a fully enclosed hollow interior 327 which accommodates the wiring. This wiring harness replaces the need for field wiring to interconnect the photovoltaic modules into an electrical array. Because the present invention has no exposed metal parts, there is no need for grounding at any point in the array. For purposes of clarity, the wiring harness 301 is broken out separately in FIG. 3B1 and FIG. 3B2, and shown as parts 303, 304, 305, and 306. The components of the wiring harness shown in the figures can be combined if desired into the wiring harness at a remote location such as a factory, away from the in-the-field installation site of the photovoltaic array. As shown in the figures, the wiring harness depicted comprises a return electrical conductor wire 303, a circular perforated reinforcing tube, 304, jumper wires 305 between adjacent framework elements, all of which are snapped onto non-conductive spacers, 306. In one embodiment, the jumper wires are terminated with high voltage connectors such as are currently employed in the art of photovoltaic arrays. In an alternative embodiment, the jumper wires are formed into coils 305a, see FIG. 3C, that are incorporated into an integrated electro-mechanical connection, as discussed below.

In one embodiment, the internal wiring harnesses employed herein can be formed as follows, although the invention is not limited to any particular method for forming the structural members: The spacers 306, as shown in FIG. 3B2, are slid onto a 15-20 foot length of a preferably circular cross-section, preferably perforated, non-conductive rigid tube 304, preferably plastic, to predetermined points along the tubing, to be prepositioned where the electrical connections are to be made to the photovoltaic modules The spacers are then affixed by any suitable means including but not limited to thermal, solvent, or adhesive bonding. Next, the electrically conductive interconnect wires, 303 and 305 are formed to shape dictated by the specific wiring scheme for each specific application. Shaping may be, but need not be, effected by bending over tooling on a bench before snapping them into place on the prepositioned spacers 306.

As shown in FIG. 3A the assembled wiring harness is then inserted into the appropriate end or intermediate member, 201, 203, and 204. In one embodiment, the interior of the end and intermediate members after insertion of the wiring harness is sealed with foam, or sealed otherwise to retard the ingress of moisture, oxygen, insects, and debris.

This internal wiring harness eliminates the need for interconnect wiring between photovoltaic modules in the field, if photovoltaic modules with an internal connector design are installed. One embodiment is shown in FIG. 3D.

Referring to FIG. 3D, in some embodiments, the framework cross members 205 contain an internal, electrical interconnect wiring harness 309. This wiring harness replaces the need for some of the field wiring required in other embodiments.

In the embodiment depicted in FIG. 3D, the wiring harness (309) is assembled from one or two electrical jumper wires 310 disposed to connect framework members, 201 and 203, having weather-tight high voltage connectors, 307 (bulkhead) or 308 (plug), all of which are fastened onto non-conductive spacers/holders, 306. Corresponding weather-tight connectors 307 (bulkhead) are installed in each framework interconnect member 202 and electrically connected to the internal wiring harness 301 depicted in FIGS. 3B1 and 3B2. The corresponding plugs in the ends of the framework cross members 205 make a continuous electrical connection with the wiring harness in the members 201, 203, or 204 upon assembly on the roof.

The internal wiring harness in cross member 205 eliminates the need for some of the interconnect wiring between photovoltaic modules during installation on a rooftop. Since the wiring is present in the cross members 205, all that is necessary during installation is to connect the framework elements mechanically and the wiring is concomitantly connected.

In the embodiment shown in FIG. 3A-3D, the plastic interconnect, 202, is in the form of a hollow rectangular shaped tube that is sized to fit into the hollow rectangular aperture of the cross-member. In the practice of the present invention, there is no particular form required for the plastic interconnect. It may, for example, be conical in shape, it may be a truncated square pyramid in shape, prismatic or any shape that will permit the ready interconnection of the end or intermediate members with the cross-members.

The plastic interconnects, 202 can for example be manufactured from appropriately sized tubing in the form of a hollow rectangular prism, cut to length and bonded to the end or intermediate members. Alternatively, the plastic interconnects can be injection molded. Any method of bonding known in the art is satisfactory including mechanical fastening, gluing; thermal bonding; dielectrical bonding; or ultrasonical bonding. The end and intermediate members can also be manufactured with integral interconnects by injection molding or compression molding.

One alternative for achieving firm, positive connection that is also reversible is to employ spring fingers 250 (shown in FIG. 3A) that are molded to or otherwise attached to the exterior surface of the tubing, that are pushed inward when cross member 205 is slid over the open face of interconnect 202 to a pre-determined position at which point the compressed fingers spring out into corresponding holes 251 in cross member 205 to lock the two framework members together. In another embodiment the holes do not penetrate the surface of the cross member. If it is desired to disassemble the framework, the spring fingers 251 can be depressed so that corresponding cross member 205 can be slid off the corresponding plastic interconnect 202. This eliminates all of the drilling and mechanical fastening required in conventional metallic frames, greatly reducing the assembly and installation time on the roof.

FIG. 4A illustrates an embodiment of a single framework element set up to hold one photovoltaic module. Shown in FIG. 4A are two alternative electrical connections, magnified in sections 4C and 4D, and the framework details of the electro-mechanical interconnection between the photovoltaic module and framing elements. Also shown are internally threaded electrically conductive standoffs FIG. 4B, 401 which are bonded to the plastic structural member 205 making up the framework element to affix the intended photovoltaic module atop the framework element. Details of the internally threaded standoffs 401 which hold the photovoltaic module are shown in magnified section of FIG. 4B. The standoffs can be attached to the framework element by installing them into mounting holes drilled into the plastic structural member by heating them with a heated threaded tip, bonding them with adhesive, solvent bonding, or ultrasonically bonding.

The magnified section illustrated in FIG. 4C shows high voltage cables 108 leading from the junction box 107 (shown in FIG. 4A) found on the back of a photovoltaic module (module not shown in FIG. 4C) are plugged into the bulkhead connectors 307 to complete the electrical circuit with the wiring harness, 301 (shown in FIG. 4A), via bulkhead connectors mounted on the member 201 of the framework element. In an embodiment, high-voltage bulkhead connectors are hardwired to the end of wiring elements 305 in the wiring harness, at a remote location, before being transported to the installation site and fastened to the corresponding framework elements 201, 203 or 204 (not shown), followed by placing of the photovoltaic module onto the framework element and securing.

Magnified sections found in FIGS. 4D and 4G illustrate embodiments wherein a coil 305a is wound on the end of a jumper wire 305 or return electrical conductor wire 303 that has the internal diameter of the internally threaded electrically conductive standoffs with insulating caps 401. By positioning the coil 305a beneath the appropriate conductive standoff 401, and inserting an appropriate-length conductive set screw 405 through 401 and into the coil the mechanical standoff doubles as an electrical connection to the photovoltaic module 104 (see FIG. 4F) from the internal wiring harness 301 when the photovoltaic module has an internally wired frame segment member as described above.

FIGS. 4E and 4F each illustrates a single framework element holding one photovoltaic module, 104, via the electro-mechanical standoffs, 401.

FIG. 4E depicts an embodiment in which the photovoltaic module has a junction box 107, interconnect wiring 108 and weather-tight connectors 109. The framework element has mating weather-tight bulkhead fittings 307. In this embodiment, prior to affixing the photovoltaic module to the framework element, the plug connectors 109 are connected to the corresponding bulkhead connectors 308. Following the electrical connection, the panel is positioned on the framework element and connected thereto using the pre-positioned mechanical standoffs 401, and attachment screws.

FIG. 4E also depicts, on the right, the case where the photovoltaic module junction box 107 is mounted close enough to the framework element 203 that only weathertight connectors 109 are needed to connect the junction box 107 to the mating weathertight bulkhead fittings 307, eliminating the cost of the interconnect wiring 108.

FIG. 4G illustrates details of an embodiment in which connectorless connections are made to the wiring harness 301. This connectorless electrical connection invention eliminates the photovoltaic module interconnect wiring 108, having the water-tight connectors 307 and 109, and the junction box 107, all shown in FIG. 4E. These are expensive items which are subject to high failure rates when directly exposed to severe outdoor environments for long periods of time.

In the embodiment depicted in FIGS. 4F and 4G, all conductors and connectors are fully enclosed within the structural members of the photovoltaic array. The junction box is eliminated. In FIG. 4F, a photovoltaic module, 104, is installed onto a frame element defined by structural members 201, 203, and 205, formed by snapping the ends of cross-members 205 onto the appendages 202 disposed on members 201 and 203. The photovoltaic module is provided with a peripheral frame, 106, which houses the wiring, 409, including the isolation diodes (not shown) commonly employed in the art, and connectors, 409a, associated with the module. In the case depicted in FIG. 4G, the connector is just a coil formed at the end of wire 409a. Referring to FIG. 4F, the frame is provided with a series of mounting holes along its surface, 450, which are located to align with the mounting standoffs 401 disposed on the upper surface of the framework element. The mounting standoffs are insulating caps disposed upon a threaded metal element, 405, disposed to receive the mounting screws, 405a. Referring to FIG. 4G, electrical connection is effected by inserting an electrically conductive mounting screw 405a through mounting hole 450 in the frame 106 of the photovoltaic module 104 where the metallic screw 405a comes into electrical contact with connection 409a within the frame, and screws into the threaded metal element 405 which in turn is in electrical contact with connector 305a, thereby forming an electrical connection between 409a and 305a. This method of electrical termination replaces the junction box 107, interconnect wiring 108 and connectors 109, at a significant cost savings, as well as long term reliability.

In the practice of the invention, the framework elements are both electrically and mechanically connected to form an integrated photovoltaic array. All the array wiring and interconnections can be performed at a remote location prior to installation on site. In the embodiment depicted in FIG. 4E, there is a need for making cable connections from the photovoltaic panel to the framework members. In the embodiment depicted in FIG. 4F-4G, there are no cable connections to be made, and the electrical and mechanical connections are made simultaneously, without the necessity of in the field wiring. Because there is no exposed wiring, and no chance of short circuits to exposed metal parts since there aren't any, there is no need for the extensive grounding of the framework such as is commonly done.

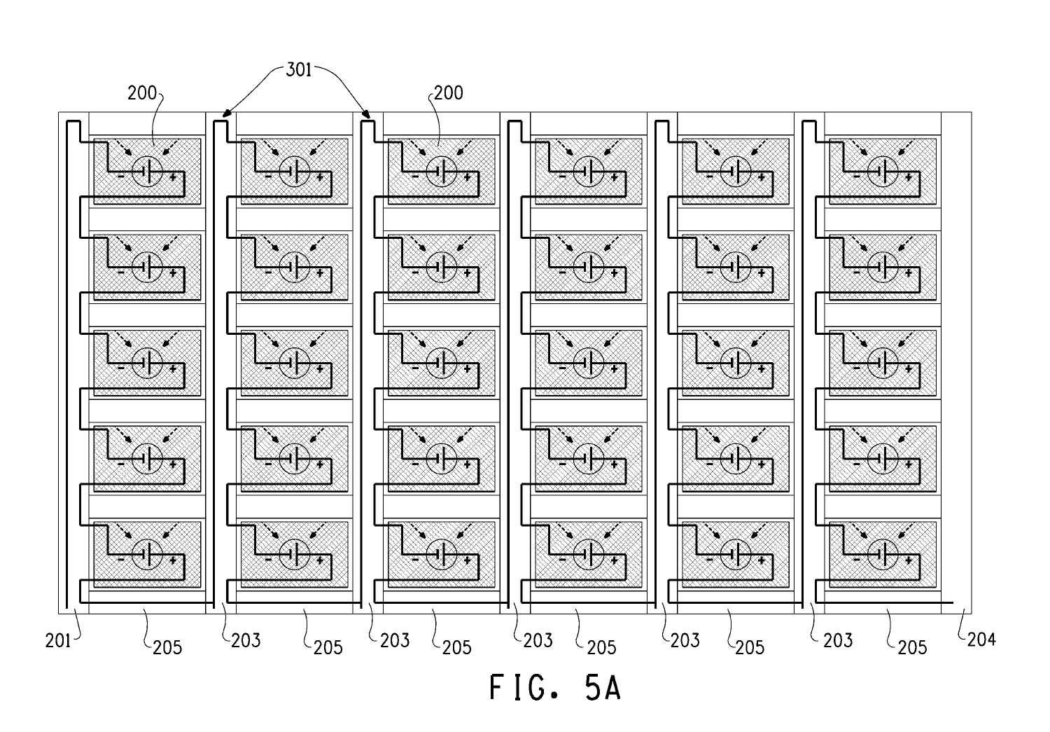

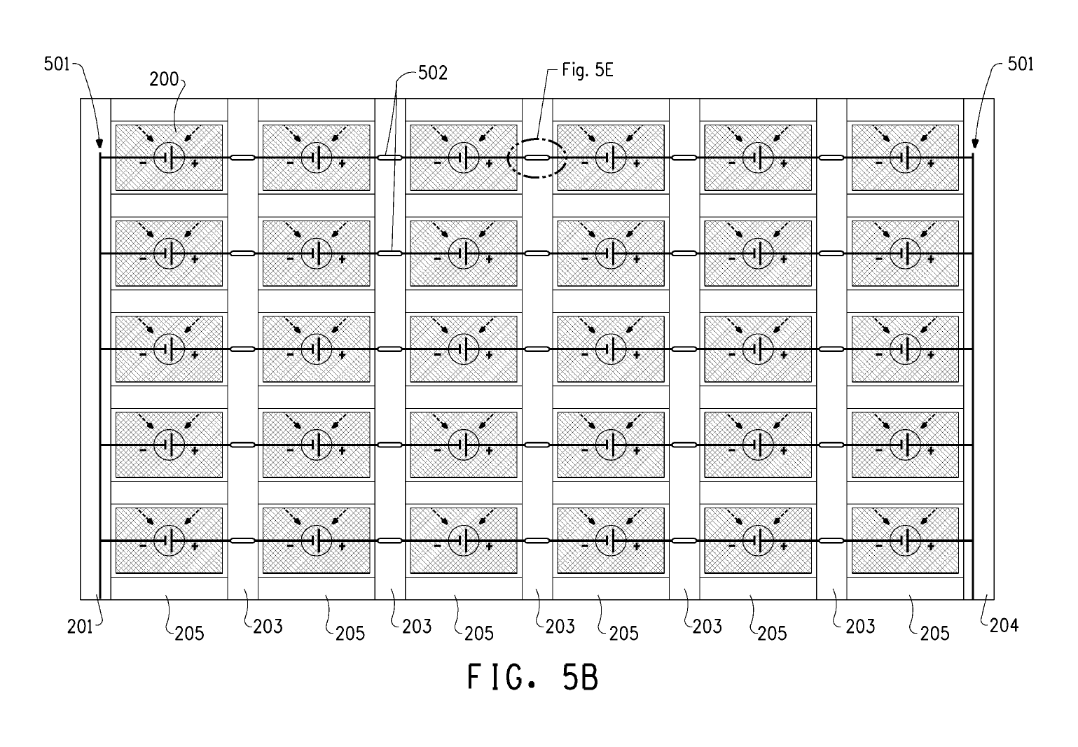

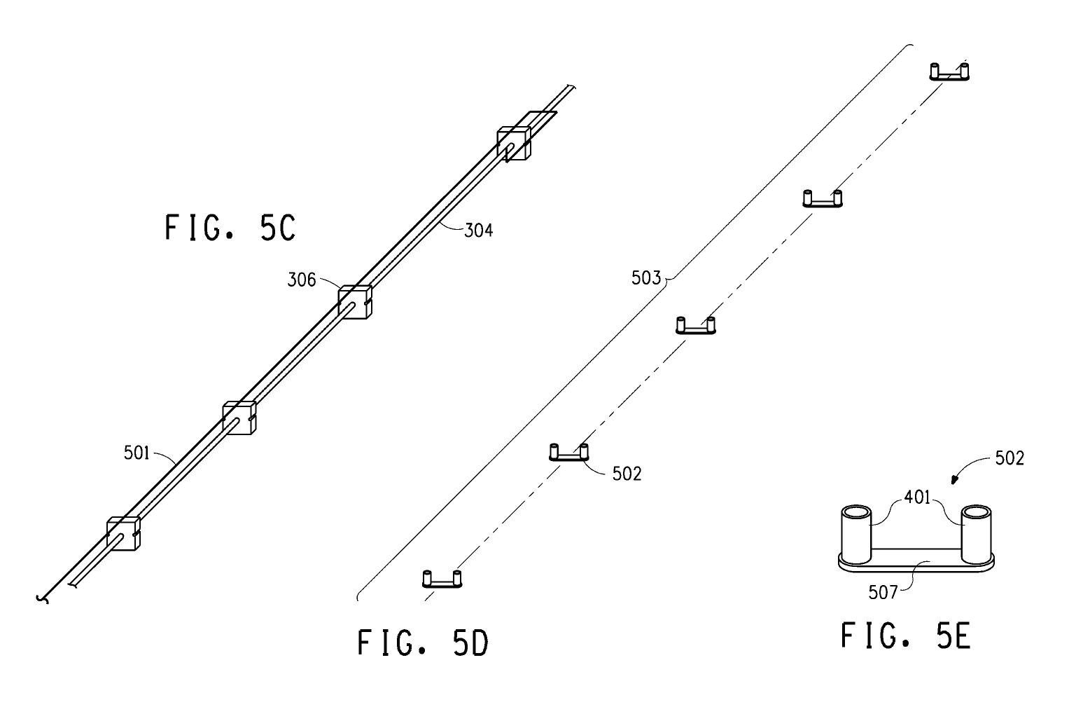

Numerous wiring configurations can be employed in forming the photovoltaic array. FIG. 5A illustrates the photovoltaic modules 200 interconnected in series, with wiring harnesses in framework members 201 and 203. In this wiring scheme, no wiring harness is required in framework element 204. Interconnect wiring is located in the lower cross members 205.

In an alternative embodiment, FIG. 5B illustrates the photovoltaic modules 200 interconnected in series left to right, and in parallel top to bottom. Wiring harnesses 501 are found in framework members 201 and 204, while framework members 203 have short conductive links 502 (see FIG. 5E) between the electro-mechanical fasteners 401 immediately adjacent to each other. These linked standoffs, 502 are inserted inside the vertical framework elements 203 at the factory instead of inserting individual standoffs 401, thereby eliminating altogether the wiring harness 301 or 501 from framework elements 203 for this embodiment. As shown in FIG. 5D, 503 indicates the regularly spaced standoff pairs that can be inserted as a single column into the framework member. This virtually eliminates all panel interconnect wiring and embodies the simplest embodiment.

FIGS. 5C and 5D show an embodiment of a method for connecting adjacent photovoltaic modules together. In FIG. 5C, a buss 501 replaces the wiring harness 301 depicted in FIG. 3B1. FIG. 5D depicts the “jumper lugs” 502 indicated in FIG. 5B; the jumper lugs are mounted on each of the inboard vertical framework elements, 203, greatly simplifying the internal wiring of the photovoltaic array and associated manufacturing costs.

FIG. 5E illustrates the detail of the “jumper lugs” 502 shown in FIG. 5D, consisting of two threaded standoffs, 401, electrically connected by a conductive link, 507.

### LEGEND FOR DRAWINGS

100—residential rooftop
101—assembled photovoltaic (PV) array
102—assembled framework mounted on roof
103—individual framework elements that together make up the framework (102)
104—generic photovoltaic (PV) modules
105—the basic PV module layered structure including the photocell array,
105pv; sandwiched between the clear, protective top layer, 105tc; and the protective bottom layer, 105pb.
106—peripheral supporting structural frame surrounding layered PV structure 105
107—electrical junction box on back of PV panel connecting wiring inside PV module to high voltage electrical leads 108
108—high voltage electrical leads connecting junction box 107 to weather-tight plugs 109
109—weather-tight plugs connecting high voltage electrical leads 108 to bulkhead connectors mounted on framework element.
110—One embodiment of a suitable PV module, structurally supported with a light-weight supporting frame, 111, via mounting holes, 112, and structural stiffeners 113 bonded to the backside of the photovoltaic module 105
111—light weight peripheral supporting frame surrounding basic layered PV structure 105
112—mounting holes in light weight peripheral supporting frame.
113—structural stiffeners bonded to backside of PV panel 110
114—alternative PV panel, with integrated backside supporting structure, framing or backing 115 bonded to backside.
115—integral backside supporting structure for panel 115.,
116—embodiment of PV panel with peripheral supporting frame
200—framework
201—framework end member, forming one side of a framework
202—framework mechanical interconnect member bonded to 201, 203, 204
203—framework intermediate member
204—framework end member, forming opposite side of framework
205—framework cross-member
207—mounting shoes, fastened to roof to support framework
208—mounting feet, fastened to framework elements, which engage the roof-mounted, mating tongue on each corresponding mounting shoe, 207
209—location of where left-most framework member 201 will be fastened to roof
210—location where right-most framework member 204 will be fastened to roof
211—location where upper-most foot of framework members 201, 203 and 204, will be fastened to roof
212—location where lower-most foot of framework members 201, 203 and 204, will be fastened to roof
213—location where feet of framework members 203 will be fastened to roof
214—location where rows of framework elements 201, 203 and 204 will be fastened to roof
Point 209,211—upper-left most mounting foot location for framework array
Point 210,211—upper-right most mounting foot location for framework array
Point 209,212—lower-left most mounting foot location for framework array
Point 210,212—lower-right most mounting foot location for framework array
250—spring finger
251—spring finger hole
301—framework element internal electrical interconnect wiring harness, both inside framework elements 201, 202 and 203
303—a return electrical conductor wire
304—a circular perforated reinforcing tube
305—jumper wires between adjacent framework elements
305a—coil of internal electrical wiring forming a connector.
306—non-conductive spacers/wire holders
307—high voltage bulkhead electrical connectors which mate with 308
308—high voltage plug-type electrical connectors which mate with 307
309—internal, electrical interconnect wiring harness in framework cross-pieces 205, which connects wiring harness in framework elements 201, 203 or 204 and consists of components 306, 307, 308, and/or 310
310—jumper wire in wiring harness inside framework crosspiece 205 to connect two adjacent photovoltaic modules
327—hollow enclosed interior
401—insulated standoffs capping mechanical fasteners 405b located in framework element which, with mating fastener, 405a, passing through mounting hole 450 hold module to framework element
405a—conductive screw which connects the module to the framework element via conductive holes 450, insulated standoffs 401, and threaded element 405. In the case of electrical connections 409a and 305a, the screw 405a also effects the electrical connection.
405—threaded conductive element disposed to receive screw 405a.
409—electrical lead from the photovoltaic module 105 routed through the surrounding plastic frame 106, to 2 of the mounting holes 450.
409a—coil formed at end of conductor 409a to served as electrical connector. 450 mounting hole in module frame.
501—electrical buss bar replacing wiring harness 301.
502—jumper lugs short conductive link inside framework element 203 to create a series electrical connection of adjacent modules in each row of the photovoltaic array
503—column of short conductive links 502 inside framework member 203
506—magnified view illustrating details of an embodiment in which a short conductive link 507 connects two adjacent mechanical fasteners 401 inside a framework element 203
507—short conductive link

1. A photovoltaic array comprising a plurality of photovoltaic modules the photovoltaic modules disposed upon and mechanically and electrically connected to a plurality of framework elements; the framework elements being mechanically and electrically interconnected to form a framework; the framework elements comprising electrically non-conductive structural members comprising internally disposed electrical conductors wherein each of the structural members in which the electrical conductors are internally disposed is an electrically non-conductive structural member, electrical and mechanical connections to the photovoltaic module disposed upon the framework element, and electrical and mechanical connections among the framework elements; the framework comprising an electrical output to permit connection to an external electrical load and wherein the output voltage of the photovoltaic array can be electrically referenced to an arbitrary voltage that is not ground.

2. The photovoltaic array of claim 1 wherein the electrically non-conductive structural members consist essentially of plastic.

3. (canceled)

4. The photovoltaic array of claim 1 wherein the photovoltaic modules comprise output connections housed within the electrically non-conductive structural members.

5. The photovoltaic array of claim 1 wherein the framework element further comprises an electro-mechanical connection between the photovoltaic module and the framework element.

6. (canceled)

7. The photovoltaic array of claim 1 wherein each of the plurality of photovoltaic modules are electrically connected to an electrical junction box, and wherein the electrical junction box to which each photovoltaic module is electrically connected is mechanically connected to one of the electrically non-conductive structural members and is electrically connected to an electrical conductor internally disposed in said one of the electrically non-conductive structural members.

8. The photovoltaic array of claim 1 wherein the structural members of the framework elements consist essentially of plastic; wherein an electro-mechanical connection exists between each photovoltaic module of the photovoltaic array and the framework element on which said photovoltaic module is disposed; and wherein the electrical connection between said photovoltaic module and said framework element on which the photovoltaic module is disposed is internal to the structural members of said framework element.

9. A method comprising illuminating a photovoltaic array with sunlight to generate an electrical current and voltage from the photovoltaic array, the photovoltaic array comprising a plurality of photovoltaic modules the photovoltaic modules disposed upon and mechanically and electrically connected to a plurality of framework elements; the framework elements being mechanically and electrically interconnected to form a framework; the framework elements comprising electrically non-conductive structural members comprising internally disposed electrical conductors wherein each of the structural members in which the electrical conductors are internally disposed is an electrically non-conductive structural member, electrical and mechanical connections to the photovoltaic module disposed upon the framework element, and electrical and mechanical connections among the framework elements, and applying the electrical voltage so generated to an external electrical load wherein the output voltage is referenced to a potential that is not ground potential.

10. (canceled)

11. (canceled)

12. (canceled)

13. (canceled)

14. (canceled)

15. (canceled)

16. (canceled)

17. (canceled)

18. A method comprising disposing a plurality of photovoltaic modules into a plurality of framework elements, the photovoltaic modules being equipped with electrical and mechanical connectors, each the framework element comprising structural members comprising internally disposed electrical conductors wherein each of the structural members in which the electrical conductors are internally disposed is an electrically non-conductive structural member, electrical and mechanical connectors to the photovoltaic module disposed upon the framework element, and electrical and mechanical connectors for interconnecting each framework element to at least one other framework element; connecting the photovoltaic module to the framework element electrically and mechanically; and, interconnecting the framework elements with one another to form a photovoltaic array whereof the output voltage can be electrically referenced to an arbitrarily selected voltage that is not ground.

19. (canceled)

20. (canceled)

21. (canceled)

22. (canceled)

23. (canceled)

24. (canceled)

25. (canceled)
